(19) United States
(12) Patent Application Publication
(10) Pub. No.: US 2026/0262349 A1
(43) Pub. Date: Sep. 3, 2026

(54) LED DISPLAY DEVICE, AND DISPLAY PANEL HAVING LED DISPLAY DEVICE AND SEGMENTATION UNIT GROUP

(71) Applicant: FOSHAN NATIONSTAR OPTOELECTRONICS CO., LTD., Foshan City, Guangdong (CN)

(72) Inventors: Kuai QIN, Foshan City, Guangdong (CN); Shaojia XIE, Foshan, Guangdong (CN); Feng GU, Foshan, Guangdong (CN); Fangping HE, Foshan, Guangdong (CN); Caineng HUO, Foshan, Guangdong (CN); Zhuang PENG, Foshan, Guangdong (CN)

(73) Assignee: FOSHAN NATIONSTAR OPTOELECTRONICS CO., LTD., Foshan, Guangdong (CN)

(21) Appl. No.: 18/878,792

(22) PCT Filed: Dec. 7, 2023
(86) PCT No.: PCT/CN2023/137145

§ 371 Date: Dec. 24, 2024

(30) Foreign Application Priority Data
Mar. 29, 2023 (CN) 202320679109.7

(51) Int. Cl. H10H 20/857; H10H 20/85; H10H 29/14

(52) U.S. Cl. CPC H10H 20/857; H10H 20/8502; H10H 29/142

(57) ABSTRACT

Disclosed are an LED display device, and a display panel having the LED display device and a segmentation unit group. The LED display device includes a substrate, a front circuit board arranged at a top of the substrate, a back circuit board arranged at a bottom of the substrate, and a light-emitting chip arranged on the front circuit board, wherein the front circuit board is provided with an A-electrode bonding pad and a B-electrode bonding pad; the A-electrode bonding pad and the B-electrode bonding pad are respectively electrically connected with the back circuit board; the light-emitting chip includes an electrode A and an electrode B; and the front circuit board is divided into a die bonding area and a non-die bonding area, wherein the light-emitting chip is located in the die bonding area of the front circuit board, and the non-die bonding area is covered with black ink.

### CROSS-REFERENCE TO RELATED APPLICATION

This application claims priority to Chinese Patent Application No. CN202320679109.7, filed to the China National Intellectual Property Administration on Mar. 29, 2023 and entitled “LED Display Device, and LED Display Panel and Segmentation Unit Group”, the disclosure of which is hereby incorporated by reference in its entirety.

### TECHNICAL FIELD

The present disclosure relates to the technical field of Light Emitting Diode (LED) display, and in particular to an LED display device and a display panel having the LED display device, and a segmentation unit group having the LED display device.

### BACKGROUND

With the continuous improvement of indoor display application technology, small-size and high-contrast LED display devices have become one of the main directions for indoor small-pitch display factories to improve product competitiveness. In conventional flip LED display devices, a flip light-emitting chip is usually die-bonded on a bonding pad by welding through solder paste. However, the solder paste used in a welding process may turn silver after melting and cover a surface of the bonding pad, and silver has a reflective property, which reduces the contrast of the display device and affects the display effect of the LED display device.

### SUMMARY

Based on this, an objective of the present disclosure is, in one aspect, to provide an LED display device, which can improve the contrast of an LED device.

The present disclosure is implemented through the following technical solution.

An LED display device includes a substrate, a front circuit board arranged at a top of the substrate, a back circuit board arranged at a bottom of the substrate, and a light-emitting chip arranged on the front circuit board. The front circuit board is provided with an A-electrode bonding pad and a B-electrode bonding pad. The A-electrode bonding pad and the B-electrode bonding pad are respectively electrically connected with the back circuit board. The light-emitting chip includes an electrode A and an electrode B which have opposite polarities, and the electrode A and the electrode B are located on a same plane. The electrode A and the electrode B are respectively die-bonded on the A-electrode bonding pad and the B-electrode bonding pad. The front circuit board is divided into a die bonding area and a non-die bonding area. The light-emitting chip is located in the die bonding area of the front circuit board, and the non-die bonding area is covered with black ink.

Compared with the related art, according to the LED display device of the present disclosure, a black ink area is formed by filling the black ink in the non-die bonding area, so that the overall contrast of the LED display device can be effectively increased to satisfy the requirements for a small-size and high-contrast display device, and the LED display device has a simple structure and high practicability.

Further, a thickness of the black ink is 5-15 μm.

Further, an orthographic projection of the light-emitting chip on the front circuit board does not overlap with the black ink, and an area of the die bonding area is larger than an area of the orthographic projection of the light-emitting chip on the front circuit board.

Further, there is a gap between an edge position of the orthographic projection of the light-emitting chip on the front circuit board and the black ink.

Further, the non-die bonding area is divided into a wiring area and a bonding area, and the A-electrode bonding pad and the B-electrode bonding pad are located in the wiring area. The wiring area is covered with the black ink, and the bonding area is not covered with the black ink.

Further, the LED display device includes at least two light-emitting chips of different colors. The front circuit board includes at least two A-electrode bonding pads and one B-electrode bonding pad. The electrode A of each light-emitting chip is die-bonded to one A-electrode bonding pad, and the electrode B of each light-emitting chip is die-bonded to the B-electrode bonding pad.

Further, the LED display device includes three light-emitting chips of different colors, namely a blue light-emitting chip, a red light-emitting chip, and a green light-emitting chip. The blue light-emitting chip, the red light-emitting chip, and the green light-emitting chip are arranged in sequence in a longitudinal direction, so that the red light-emitting chip is located between the blue light-emitting chip and the green light-emitting chip.

In another aspect, the present disclosure further provides an LED display panel, including any of the above LED display devices.

In still another aspect, the present disclosure provides a segmentation unit group having an LED display device, including at least two unsegmented LED display devices as described above. Substrates of the LED display devices are coplanar and connected as a whole to form a substrate plate. The substrate plate between two adjacent LED display devices is provided with a conductive through hole shared by at least two LED display devices, the front circuit board and the back circuit board of the LED display device are electrically connected through the conductive through hole, and the conductive through hole is filled with a filler.

Further, the filler is the black ink or green ink.

For better understanding and implementation, the present disclosure is described in detail below with reference to the accompanying drawings.

### BRIEF DESCRIPTION OF THE DRAWINGS

FIG. 1 is a front view of a first implementation of an LED display device of the present disclosure.

FIG. 2 is a top view of the first implementation of the LED display device of the present disclosure.

FIG. 3 is a front view of the LED display device encapsulated with an encapsulation adhesive of the present disclosure.

FIG. 4 is a top view of an optimized solution of the first implementation of the LED display device of the present disclosure.

FIG. 5 is a top view of a second implementation of an LED display device of the present disclosure.

FIG. 6 is a top view of an optimized solution of the second implementation of the LED display device of the present disclosure.

FIG. 7 is a top view of an implementation of a segmentation unit group having an LED display device of the present disclosure.

FIG. 8 is a cross-sectional view of a fully plugged conductive through hole in the segmentation unit group having the LED display device of the present disclosure.

Reference signs: 1. Substrate plate;
a. LED display device; 10. Substrate; 100. Conductive through hole; 101. Filler;
20. Front circuit board; 20a. Die bonding area; 200b. Bonding area in non-die bonding area; 201. A-electrode bonding pad; 202. B-electrode bonding pad;
30. Back circuit board; 301. A-electrode pin; 302. B-electrode pin;
40. Light-emitting chip; 401. Blue light-emitting chip; 402. Red light-emitting chip; 403. Green light-emitting chip;
50. Solder;
60. Black ink;
70. Encapsulation adhesive.

### DETAILED DESCRIPTION OF THE EMBODIMENTS

In the description of the present disclosure, it is to be understood that the orientations or positional relationships indicated by the terms “center”, “longitudinal”, “transverse”, “upper”, “down”, “front”, “rear”, “left”, “right”, “vertical”, “horizontal”, “top”, “bottom”, “interior”, “exterior”, etc. are based on the orientations or positional relationships shown in the drawings, and are only for the convenience of describing the present disclosure and simplifying the description. The description does not indicate or imply that the device or element referred to must have a specific orientation, be constructed and operated in a specific orientation, and therefore cannot be construed as limiting the present disclosure. In the description of the present disclosure, unless otherwise stated, “plurality” means two or more than two.

It is to be noted that when an element is referred to as being “fixed to” another element, it may be directly on another element or there may also be a centered element. When an element is considered to be “connected” or “fixedly connected” to another element, it may be directly connected to another element or there may also be a centered element at the same time.

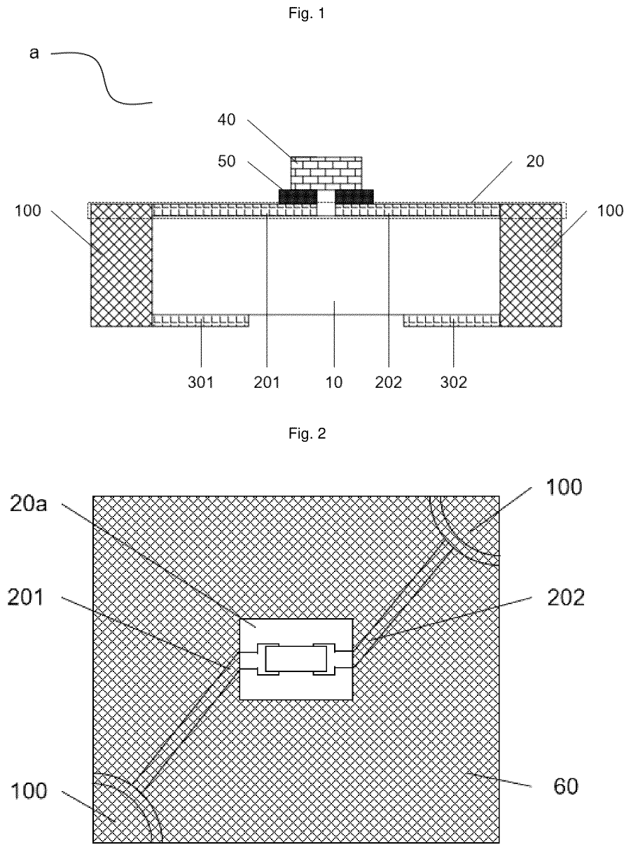

FIG. 1 and FIG. 2 show a specific structure of an implementation of an LED display device of the present disclosure. As shown in FIG. 1 and FIG. 2, in this implementation, the LED display device includes a substrate 10, a front circuit board 20 arranged at a top of the substrate 10, a back circuit board 30 arranged at a bottom of the substrate 10, and a light-emitting chip 40 die-bonded to a top of the front circuit board 20 by solder 50. The solder 50 is specifically solder paste.

Specifically, the substrate 10 is square. An A-electrode bonding pad 201 and a B-electrode bonding pad 202 are arranged on the front circuit board 20, and the back circuit board 30 is provided with an A-electrode pin 301 and a B-electrode pin 302. One end of the A-electrode bonding pad 201 is electrically connected with the A-electrode pin 301 through a conductive through hole 100 penetrating through the top and bottom of the substrate 10, and the other end is a free end. One end of the B-electrode bonding pad 202 is electrically connected with the B-electrode pin 302 through the conductive through hole 100, and the other end is a free end. Of course, the conductive through hole 100 here can also be a solid conductive column. The light-emitting chip 40 is specifically a flip light-emitting chip, and an electrode A and an electrode B of the light-emitting chip 40 are respectively die-bonded on the free end of the A-electrode bonding pad 201 and the free end of the B-electrode bonding pad 202. The electrode A of the light-emitting chip 40 can be a negative electrode or a positive electrode, and a polarity of the electrode B opposite to that of the electrode A.

The front circuit board 20 is divided into a die bonding area 20a and a non-die bonding area. The die bonding area 20a is located in the middle of the front circuit board 20, and the non-die bonding area is located at a peripheral edge of the front circuit board 20 and surrounds the die bonding area 20a. The light-emitting chip 40 is located in the die bonding area 20a, while most of the A-electrode bonding pad 201 and the B-electrode bonding pad 202, as well as the conductive through hole 100 are located in the non-die bonding area. The non-die bonding area is covered with blank ink, that is, surfaces of the A-electrode bonding pad 201, the B-electrode bonding pad 202, and the conductive through hole 100 in the non-die bonding area are also covered with the blank ink 60. When the black ink 60 covers the conductive through hole 100, a solid substance needs to be filled in the conductive through hole 100 to support the black ink 60.

Compared with the conventional face-up LED display device, since the electrode A and the electrode B of the flip light-emitting chip are directly soldered to the A-electrode bonding pad 201 and the B-electrode bonding pad 202, there is no need to connect the light-emitting chip with the A-electrode bonding pad 201 and the B-electrode bonding pad 202 through metal wires, so that emergent light is not blocked by the wires, which helps to improve the brightness and contrast of the display device. In addition, by coating the non-die bonding area of the front circuit board 20 with the black ink 60, the blackness of an upper surface of the substrate 10 is increased, thereby improving the contrast of the whole LED display device. Of course, the higher the blackness of the black ink 60, the better the contrast effect.

Further, a thickness of the black ink 60 is 5-15 μm. The larger the thickness of the black ink 60, the higher the contrast of the LED display device. Therefore, if the thickness of the black ink 60 is too small, the contrast enhancement effect is not obvious. However, considering that the light-emitting chip 40 is die-bonded on the A-electrode bonding pad 201 and the B-electrode bonding pad 202 by using the solder 50, there are certain requirements for the maximum thickness of the solder 50. If the thickness of the black ink 60 is too large, the thickness of the solder 50 also needs to be increased proportionally. In this way, the thickness of the solder 50 may not meet the process requirements, so that the thickness of the black ink 60 cannot be too large.

Further, an orthographic projection of the light-emitting chip 40 in the above LED display device on the front circuit board 20 does not overlap with the black ink 60, and an area of the die bonding area 20a is larger than an area of the orthographic projection of the light-emitting chip 40 on the front circuit board 20. Preferably, there is a gap between an edge position of the orthographic projection of the light-emitting chip 40 on the die bonding area 20a and the black ink 60. In this way, the black ink 60 is at a certain distance from the light-emitting chip 40, which can avoid water vapor from entering the light-emitting chip 40 along the gap between the black ink 60 and the substrate 10.

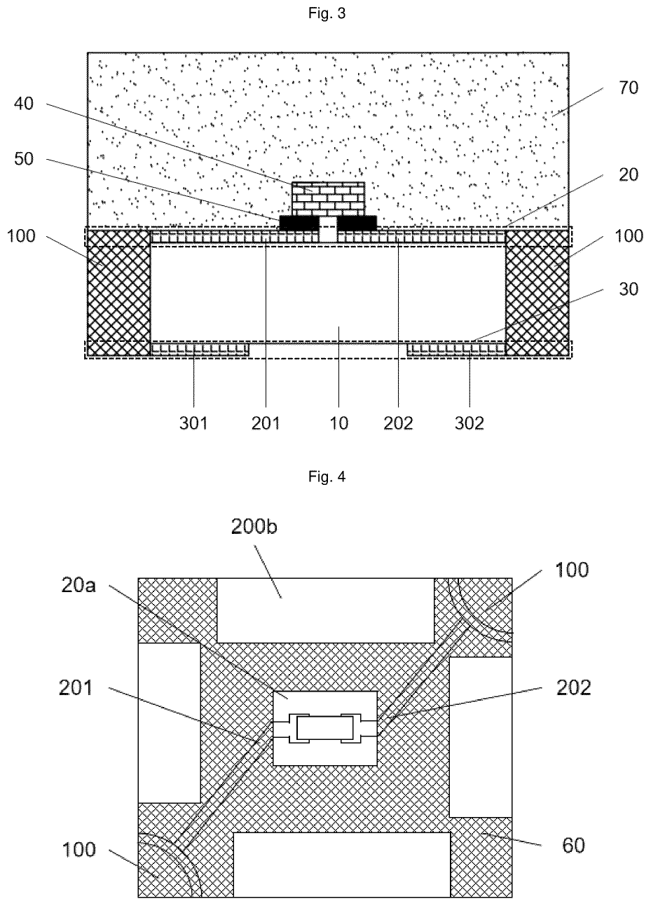

As shown in FIG. 3, the LED display device usually needs to be filled with an encapsulation adhesive 70 after die bonding to isolate air and water vapor. However, since the bonding ability between the encapsulation adhesive 70 and the black ink 60 is weaker than the bonding ability between the encapsulation adhesive 70 and the substrate 10, external water vapor easily enters the interior of the LED display device along the gap between the black ink 60 and the substrate 10. Therefore, in some implementations, the non-die bonding area of the front circuit board 20 is further divided into a wiring area and a bonding area 200b. As shown in FIG. 4, the A-electrode bonding pad 201 and the B-electrode bonding pad 202 in the non-die bonding area are located in the wiring area, other areas outside the wiring area are the bonding area 200b, and the bonding area 200b is located at a peripheral edge of the substrate 10. The wiring area is covered with the black ink 60, and the black ink 60 covers surfaces of the A-electrode bonding pad 201 and the B-electrode bonding pad 202. The bonding area 200b is covered with the black ink 60. In this way, when the LED display device is filled with the encapsulation adhesive 70, the encapsulation adhesive 70 in the bonding area 200b is directly bonded to the substrate 10, thereby improving the sealing performance of the LED display device and further improving the reliability of the device by improving the bonding ability between the encapsulation adhesive 70 and the LED display device.

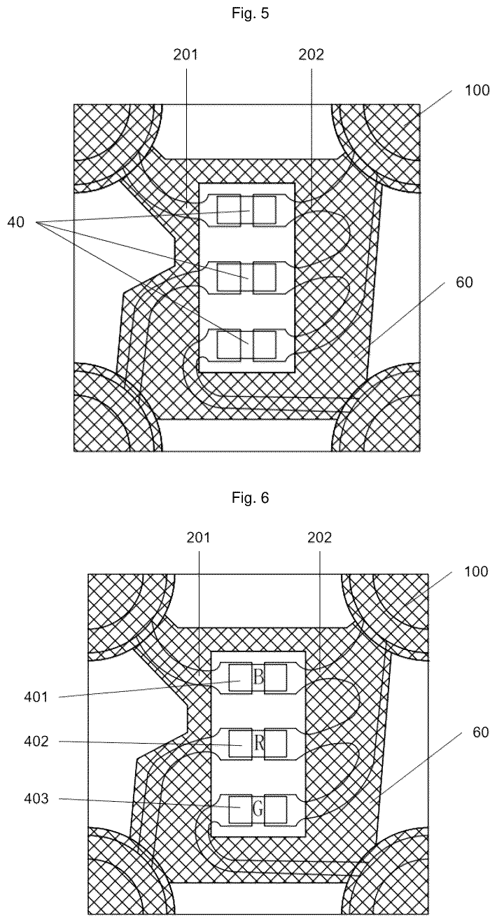

FIG. 5 shows a specific structure of a second implementation of an LED display device of the present disclosure. As shown in FIG. 5, compared with the first implementation, the LED display device of this implementation differs in that the LED display device of this implementation includes three light-emitting chips 40 of different colors, and the front circuit board 20 is provided with three A-electrode bonding pads 201 and one B-electrode bonding pad 202. It is to be noted here that when the LED display device includes a plurality of light-emitting chips 40, the area of the die bonding area 20a of the front circuit board 20 is larger than the sum of the areas of the orthographic projections of the light-emitting chips 40 on the front circuit board 20, so as to avoid the distance between the light-emitting chips 40 and the black ink 60 being too close.

Specifically, three light-emitting chips 40 of different colors are arranged in a “1” shape in a longitudinal direction. The electrode A of each light-emitting chip 40 is die-bonded to one A-electrode bonding pad 201, and the electrode B of each light-emitting chip 40 is die-bonded to the same B-electrode bonding pad 202. Correspondingly, the back circuit board 30 is provided with three A-electrode pins 301 and one B-electrode pin 302 corresponding to the A-electrode bonding pads 201 and the B-electrode bonding pad 202, each A-electrode pin 301 is electrically connected with one A-electrode bonding pad 201, and the B-electrode pin 302 is electrically connected with the B-electrode bonding pad 202. The electrode A of each light-emitting chip 40 is die-bonded to one A-electrode bonding pad 201, and the electrode B of each light-emitting chip 40 is die-bonded to the same B-electrode bonding pad 202. The electrode A of the light-emitting chip 40 in this implementation can also be a negative electrode or a positive electrode, and a polarity of the electrode B is opposite to that of the electrode A.

When the electrode A is the positive electrode and the electrode B is the negative electrode, the A-electrode bonding pad 201 is a positive electrode bonding pad, and the A-electrode pin 301 electrically connected therewith is a positive electrode pin. In this way, the LED display device forms a common cathode structure, which can provide different voltages according to the requirements for the working voltages of the light-emitting chips 40 of different colors without the need to arrange additional shunt resistors, so as to reduce the power consumption.

When the electrode A is the negative electrode, the A-electrode bonding pad 201 is a negative electrode bonding pad, and the A-electrode pin 301 electrically connected therewith is a negative electrode pin. In this way, the LED display device forms a common anode structure, which can realize unified power supply for the plurality of light-emitting chips 40 of different colors.

In some embodiments, the above LED display device having the common cathode structure includes three light-emitting chips 40, namely a blue light-emitting chip 401, a red light-emitting chip 402, and a green light-emitting chip 403. As shown in FIG. 6, the blue light-emitting chip 401, the red light-emitting chip 402, and the green light-emitting chip 403 are arranged in sequence in the longitudinal direction, so that the red light-emitting chip 402 is located between the blue light-emitting chip 401 and the green light-emitting chip 403. Since the material of the red light-emitting chip 402 is more fragile than the material of the light-emitting chips of two other colors, the red light-emitting chip 402 is prone to failure when being close to the edge position. Therefore, by arranging the red light-emitting chip 402 between the blue light-emitting chip 401 and the green light-emitting chip 403, the reliability of the LED display device can be improved.

In addition, the present disclosure further provides an LED display panel, including any of the above LED display devices.

In the actual production of the LED display devices, a plurality of LED display devices which are connected together and arranged in a matrix are formed on a whole large substrate plate, and then cut into single LED display devices with a wafer incision machine. Since through holes penetrating through the top and bottom of the substrate plate need to be drilled on the substrate plate, and then conductive through holes for connecting an A-electrode bonding pad and an A-electrode pin, and for connecting a B-electrode bonding pad and a B-electrode pin are formed in the through holes by electroplating. However, since tin for fixing a chip easily penetrates a surface of a component from the conductive through hole and causes a short circuit, in order to solve this problem, a lower part of the conductive through hole is conventionally filled with an insulating material (such as ink), that is, half-plugging is achieved. However, since the substrate plate has larger area and is thinner, and a stress coefficient of the ink is different from a stress coefficient of the substrate plate, if the conventional half-plugging is used, more serious warping is caused, thereby affecting the flatness of the cutting.

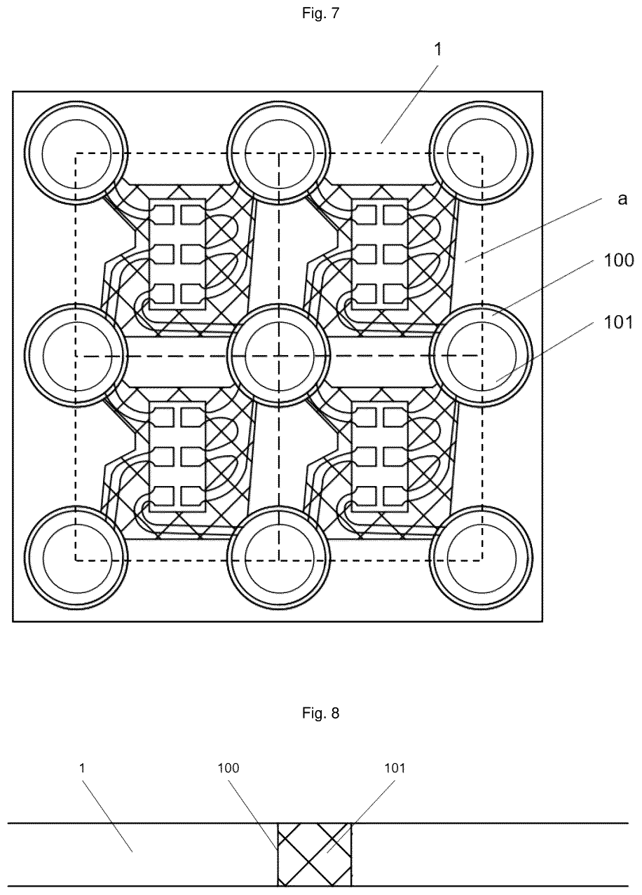

In order to solve the problem of warping of the above substrate plate 1, the present disclosure further provides a segmentation unit group having an LED display device. As shown in FIG. 7 and FIG. 8, the segmentation unit group having the LED display device includes at least two above LED display devices which are not segmented and separated. The LED display devices are distributed in a matrix, and the substrates 10 of the LED display devices are coplanar and connected as a whole to form a square or rectangular substrate plate 1.

In order to specifically illustrate the structure of the segmentation unit group having the LED display device, a segmentation unit group including four LED display devices a is taken as an example below.

The segmentation unit group in this implementation includes four LED display devices a which are not segmented and separated, the four LED display devices a are distributed in a matrix, the substrate plate 1 between any two adjacent LED display devices a is respectively provided with conductive through holes 100 shared by the two LED display devices a, and the conductive through hole 100 at the center of the four LED display devices a is shared by the four LED display devices a. Here, the number of conductive through holes 100 is not limited to that shown in FIG. 7, but is determined according to the number of A-electrode bonding pads 201 or B-electrode bonding pads 202 in the LED display device a, and the distribution manner of the conductive through holes 100 is also determined according to the wiring manner of the A-electrode bonding pad 201 or B-electrode bonding pad 202 in the LED display device a. The cross-section of the conductive through hole 100 is specifically circular, and each conductive through hole 100 is filled with a filler 101. The filler 101 is green ink or black ink. Since the green ink has better adhesion, the filler 101 is preferably green ink. In this way, by fully plugging the conductive through hole 100, the stress distribution on top and bottom surfaces of the complete substrate plate 1 before cutting is balanced, thereby avoiding the substrate plate 1 from warping and affecting the flatness of the cutting.

Compared with the related art, according to the LED display device of the present disclosure, the non-die bonding area is covered with the black ink, so that the overall contrast of the LED display device can be effectively increased to satisfy the requirements for a small-size and high-contrast display device, and the LED display device has a simple structure and high practicability. In addition, the segmentation unit group having the LED display device of the present disclosure solves the problem of warping caused by unbalanced stress on two sides of the complete substrate plate before cutting by fully plugging the conductive through hole.

The above embodiments are merely illustrative of several implementations of the present disclosure with specific and detailed description, and are not to be construed as limiting the patent scope of the present disclosure. It is to be noted that a number of variations and modifications may be made by those of ordinary skill in the art without departing from the conception of the present disclosure, and the present disclosure is also intended to include these variations and modifications.

1. An LED display device, comprising a substrate, a front circuit board arranged at a top of the substrate, a back circuit board arranged at a bottom of the substrate, and a light-emitting chip arranged on the front circuit board, wherein the front circuit board is provided with an A-electrode bonding pad and a B-electrode bonding pad; the A-electrode bonding pad and the B-electrode bonding pad are respectively electrically connected with the back circuit board; the light-emitting chip comprises an electrode A and an electrode B which have opposite polarities, and the electrode A and the electrode B are located on a same plane of the light-emitting chip; the electrode A and the electrode B are respectively die-bonded on the A-electrode bonding pad and the B-electrode bonding pad, wherein,
the front circuit board is divided into a die bonding area and a non-die bonding area; and the light-emitting chip is located in the die bonding area of the front circuit board, and the non-die bonding area is covered with black ink.

2. The LED display device according to claim 1, wherein,
a thickness of the black ink is 5-15 μm.

3. The LED display device according to claim 1, wherein,
an orthographic projection of the light-emitting chip on the front circuit board does not overlap with the black ink, and an area of the die bonding area is larger than an area of the orthographic projection of the light-emitting chip on the front circuit board.

4. The LED display device according to claim 3, wherein,
there is a gap between an edge position of the orthographic projection of the light-emitting chip on the front circuit board and the black ink.

5. The LED display device according to claim 1, wherein,
the non-die bonding area is divided into a wiring area and a bonding area, and the A-electrode bonding pad and the B-electrode bonding pad are located in the wiring area; and
the wiring area is covered with the black ink, and the bonding area is not covered with the black ink.

6. The LED display device according to claim 1, wherein,
the LED display device comprises at least two light-emitting chips of different colors;
the front circuit board comprises at least two A-electrode bonding pads and one B-electrode bonding pad; and
the electrode A of each light-emitting chip is die-bonded to one A-electrode bonding pad, and the electrode B of each light-emitting chip is die-bonded to the B-electrode bonding pad.

7. The LED display device according to claim 6, wherein,
the LED display device comprises three light-emitting chips of different colors, wherein the three light-emitting chips of different colors are respectively a blue light-emitting chip, a red light-emitting chip, and a green light-emitting chip; and the blue light-emitting chip, the red light-emitting chip, and the green light-emitting chip are arranged in sequence in a longitudinal direction, so that the red light-emitting chip is located between the blue light-emitting chip and the green light-emitting chip.

8. An LED display panel, comprising the LED display device according to claim 1.

9. A segmentation unit group having an LED display device, comprising at least two unsegmented LED display devices according to claim 1, wherein substrates of the LED display devices are coplanar and connected as a whole to form a substrate plate; and
the substrate plate between two adjacent LED display devices is provided with a conductive through hole shared by at least two adjacent LED display devices, the front circuit board and the back circuit board of the LED display device are electrically connected through the conductive through hole, and the conductive through hole is filled with a filler.

10. The segmentation unit group having the LED display device according to claim 9, wherein,
the filler is the black ink or green ink.

11. The LED display panel according to claim 8, wherein,
a thickness of the black ink is 5-15 μm.

12. The LED display panel according to claim 8, wherein,
an orthographic projection of the light-emitting chip on the front circuit board does not overlap with the black ink, and an area of the die bonding area is larger than an area of the orthographic projection of the light-emitting chip on the front circuit board.

13. The LED display panel according to claim 12, wherein,
there is a gap between an edge position of the orthographic projection of the light-emitting chip on the front circuit board and the black ink.

14. The LED display panel according to claim 8, wherein,
the non-die bonding area is divided into a wiring area and a bonding area, and the A-electrode bonding pad and the B-electrode bonding pad are located in the wiring area; and
the wiring area is covered with the black ink, and the bonding area is not covered with the black ink.

15. The LED display panel according to claim 8, wherein,
the LED display device comprises at least two light-emitting chips of different colors;
the front circuit board comprises at least two A-electrode bonding pads and one B-electrode bonding pad; and
the electrode A of each light-emitting chip is die-bonded to one A-electrode bonding pad, and the electrode B of each light-emitting chip is die-bonded to the B-electrode bonding pad.

16. The LED display panel according to claim 15, wherein,
the LED display device comprises three light-emitting chips of different colors, wherein the three light-emitting chips of different colors are respectively a blue light-emitting chip, a red light-emitting chip, and a green light-emitting chip; and the blue light-emitting chip, the red light-emitting chip, and the green light-emitting chip are arranged in sequence in a longitudinal direction, so that the red light-emitting chip is located between the blue light-emitting chip and the green light-emitting chip.

17. The segmentation unit group having the LED display device according to claim 9, wherein,
a thickness of the black ink is 5-15 μm.

18. The segmentation unit group having the LED display device according to claim 9, wherein,
an orthographic projection of the light-emitting chip on the front circuit board does not overlap with the black ink, and an area of the die bonding area is larger than an area of the orthographic projection of the light-emitting chip on the front circuit board.

19. The segmentation unit group having the LED display device according to claim 18, wherein,
there is a gap between an edge position of the orthographic projection of the light-emitting chip on the front circuit board and the black ink.

20. The segmentation unit group having the LED display device according to claim 9, wherein,
the non-die bonding area is divided into a wiring area and a bonding area, and the A-electrode bonding pad and the B-electrode bonding pad are located in the wiring area; and
the wiring area is covered with the black ink, and the bonding area is not covered with the black ink.
